(19) United States
(12) Patent Application Publication
(10) Pub. No.: US 2013/0235646 A1
(43) Pub. Date: Sep. 12, 2013

(54) SEMICONDUCTOR MEMORY DEVICE

(71) Applicants: Yasuhiro NOJIRI, Yokohama-shi (JP); Hiroyuki Fukumizu, Yokohama-shi (JP); Katsuyuki Sekine, Yokkaichi-shi (JP); Yutaka Ishibashi, Yokkaichi-shi (JP)

(72) Inventors: Yasuhiro NOJIRI, Yokohama-shi (JP); Hiroyuki Fukumizu, Yokohama-shi (JP); Katsuyuki Sekine, Yokkaichi-shi (JP); Yutaka Ishibashi, Yokkaichi-shi (JP)

(73) Assignee: KABUSHIKI KAISHA TOSHIBA, Minato-ku (JP)

(21) Appl. No.: 13/601,084

(22) Filed: Aug. 31, 2012

(30) Foreign Application Priority Data
Dec. 12, 2011 (JP) 2011-270917

(51) Int. Cl. G11C 13/00

(52) U.S. Cl. CPC G11C 13/0002
USPC 365/148

(57) ABSTRACT

A memory cell array is configured as an arrangement of memory cells disposed at intersections of a plurality of first lines and a plurality of second lines formed so as to intersect one another, each of the memory cells comprising a variable resistance element. A control circuit selectively drives the first lines and the second lines. The variable resistance element is configured by a transition metal oxide film. An electrode connected to the variable resistance element includes a polysilicon electrode configured from polysilicon. A block layer is formed between the polysilicon electrode and the variable resistance element.

### CROSS REFERENCE TO RELATED APPLICATIONS

This application is based on and claims the benefit of priority from prior Japanese Patent Application No. 2011-270917, filed on Dec. 12, 2011, the entire contents of which are incorporated herein by reference.

### FIELD

Embodiments described in the present specification relate to a semiconductor memory device.

### BACKGROUND

In recent years, resistance varying memory is receiving attention as a potential successor to flash memory. Resistance varying memory is generally configured by memory cells arranged in a matrix at intersections of a plurality of bit lines and a plurality of word lines intersecting the bit lines, each of the memory cells comprising a variable resistance element and a rectifying element.

Such a memory cell of resistance varying memory is formed connecting in series the variable resistance element which has a property that its resistance value changes by application of a voltage or the like, and a selector element which is a diode or the like. In such a memory cell, it may occur that characteristics of the variable resistance element or the selector element change, whereby variations in characteristics among memory cells may occur. Therefore, a memory cell in which such changes in characteristics are suppressed is desired.

### BRIEF DESCRIPTION OF THE DRAWINGS

FIG. 1 is a schematic view of a nonvolatile semiconductor memory device according to a first embodiment.

FIG. 2 is a perspective view showing a stacking structure 10A of a memory cell array 10.

FIG. 3 is a perspective view showing a stacking structure 10B of the memory cell array 10.

FIG. 4 is a perspective view showing a stacking structure 10C of the memory cell array 10.

FIG. 5 is a cross-sectional view showing a configuration of a memory layer 60 in a comparative example.

FIG. 6 is a cross-sectional view showing a configuration of a memory cell layer 60 in the first embodiment.

FIG. 7 is a graph explaining problems of the comparative example.

FIG. 8 is a graph explaining problems of the comparative example.

FIG. 9 is a graph explaining advantages of the first embodiment.

FIG. 10 is a graph explaining advantages of the first embodiment.

FIG. 11 is a graph explaining advantages of the first embodiment.

FIG. 12 describes advantages of the first embodiment.

FIG. 13 describes advantages of the first embodiment.

FIG. 14 describes advantages of the first embodiment.

FIG. 15 is a schematic diagram of a nonvolatile semiconductor memory device according to the first embodiment.

### DETAILED DESCRIPTION

A semiconductor memory device in an embodiment described below comprises a memory cell array configured as an arrangement of memory cells disposed at intersections of a plurality of first lines and a plurality of second lines formed so as to intersect one another, each of the memory cells comprising a variable resistance element. A control circuit selectively drives the first lines and the second lines. The variable resistance element is configured by a transition metal oxide film. An electrode connected to the variable resistance element includes a polysilicon electrode configured from polysilicon. A block layer is formed between the polysilicon electrode and the variable resistance element.

Embodiments of the present invention are exemplified below with reference to the drawings. Note that in each of the drawings, identical symbols are assigned to similar configurative elements, and detailed descriptions of such elements are omitted where appropriate. In addition, arrow X, arrow Y, and arrow Z in the drawings indicate mutually perpendicular directions.

### First Embodiment

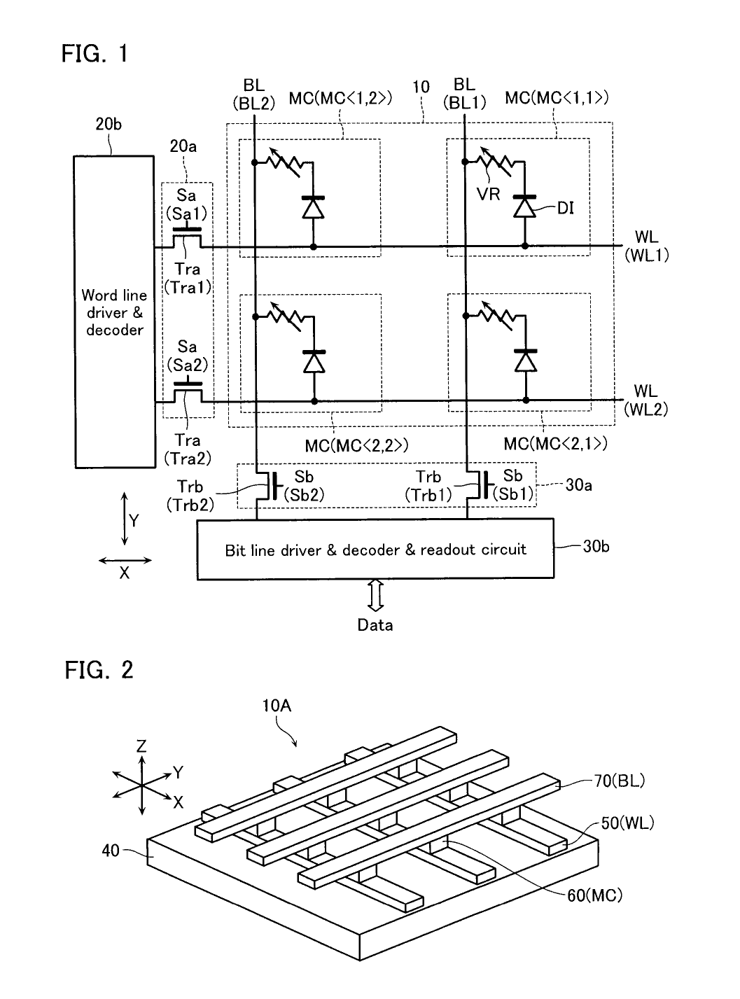

First, an overview of a nonvolatile semiconductor memory device according to a first embodiment is described with reference to FIG. 1. FIG. 1 is a schematic view of the nonvolatile semiconductor memory device according to the first embodiment.

As shown in FIG. 1, the nonvolatile semiconductor memory device includes a memory cell array 10, a word line selector circuit 20a, a word line drive circuit 20b, a bit line selector circuit 30a, and a bit line drive circuit 30b.

The memory cell array 10 includes word lines WL (WL1 and WL2) and bit lines BL (BL1 and BL2) intersecting one another, and memory cells MC (MC<1, 1>-MC<2, 2>) disposed at intersections of the word lines WL and the bit lines BL.

The word lines WL are formed extending in an X direction and arranged with a certain pitch in a Y direction. The bit lines BL are formed extending in the Y direction and arranged with a certain pitch in the X direction. The memory cells MC (MC<1, 1>-MC<2, 2>) are disposed in a matrix on a surface formed in the X direction and the Y direction.

Each of the memory cells MC includes a diode DI and a variable resistance element VR connected in series. The diode DI functions as a selector element for allowing a desired current to flow only in a selected memory cell MC.

The variable resistance element VR is capable of being repeatedly changed between a low-resistance state and a high-resistance state by application of a voltage or supply of a current. The memory cell MC stores data in a nonvolatile manner based on resistance values in these two states. The diode DI has its anode connected to the word line WL and its cathode connected to one end of the variable resistance element VR. The other end of the variable resistance element VR is connected to the bit line BL.

The word line selector circuit 20a includes a plurality of select transistors Tra (Tra1 and Tra2). Each of the select transistors Tra has its one end connected to one end of the word line WL and its other end connected to the word line drive circuit 20b. Gates of the select transistors Tra are supplied with signals Sa (Sa1 and Sa2). Control of the signal Sa results in the word line selector circuit 20a selectively connecting the word line WL to the word line drive circuit 20b.

The word line drive circuit 20b applies to the word line WL a voltage required in erase of data stored in the memory cell MC, write of data to the memory cell MC, and readout of data from the memory cell MC. In addition, the word line drive circuit 20b supplies to the word line WL a current required in erase of data, write of data, and readout of data.

The bit line selector circuit 30a includes a plurality of select transistors Trb (Trb1 and Trb2). Each of the select transistors Trb has its one end connected to one end of the bit line BL and its other end connected to the bit line drive circuit 30b. Gates of the select transistors Trb are supplied with signals Sb (Sb1 and Sb2). Control of the signal Sb results in the bit line selector circuit 30a selectively connecting the bit line BL to the bit line drive circuit 30b.

The bit line drive circuit 30b applies to the bit line BL a voltage required in erase of data stored in the memory cell MC, write of data to the memory cell MC, and readout of data from the memory cell MC. The bit line drive circuit 30b supplies to the bit line BL a current required in erase of data, write of data, and readout of data. In addition, the bit line drive circuit 30b outputs data read-out via the bit line BL to external.

[Stacking Structure]

Next, a stacking structure of the memory cell array 10 is described with reference to FIGS. 2-4. FIGS. 2-4 are schematic perspective views showing the stacking structure of the memory cell array 10.

The memory cell array 10 is configured by a stacking structure 10A shown in FIG. 2. The stacking structure 10A includes, stacked on an upper surface of a substrate 40 in a Z direction from a lower layer to an upper layer, a first conductive layer 50, a memory layer 60, and a second conductive layer 70. The first conductive layer 50 herein functions as the previously-mentioned word lines WL.

The memory layer 60 functions as the previously-mentioned memory cells MC. The second conductive layer 70 functions as the previously-mentioned bit lines BL. That is, the stacking structure 10A (memory cell array 10) has a so-called cross-point type configuration in which the memory layer 60 (memory cells MC) is disposed at intersections of the first conductive layer 50 (word lines WL) and the second conductive layer 70 (bit lines BL).

The first conductive layer 50 is formed in stripes extending in the X direction and having a certain pitch in the Y direction. The first conductive layer 50 is formed from a conductive material (for example, a metal, or the like). The first conductive layer 50 is preferably formed from a material of high heat resistance and low resistance value. For example, tungsten (W), titanium (Ti), tantalum (Ta), and their nitrides, or stacks of these metals and their nitrides, maybe employed as the material.

The memory layer 60 is provided above the first conductive layer 50 and are disposed in a matrix in the X direction and the Y direction.

The second conductive layer 70 is formed in stripes extending in the Y direction and having a certain pitch in the X direction. The second conductive layer 70 is formed so as to be in contact with an upper surface of the memory layer 60. The second conductive layer 70 is preferably formed from a material of high heat resistance and low resistance value. For example, tungsten (W), titanium (Ti), tantalum (Ta), and their nitrides, or stacks of these metals and their nitrides, may be employed as the material. Note that the first conductive layer 50 and the second conductive layer 70 may be formed from the same material or may be formed from a different material.

The stacking structure 10A shown in FIG. 2 includes a single first conductive layer 50, a single memory layer 60, and a single second conductive layer 70. That is, when configuring the memory cell array along multiple layers, the first conductive layer 50, the memory layer 60, and the second conductive layer 70 are formed alternately. However, the memory cell array 10 is not limited to the stacking structure 10A.

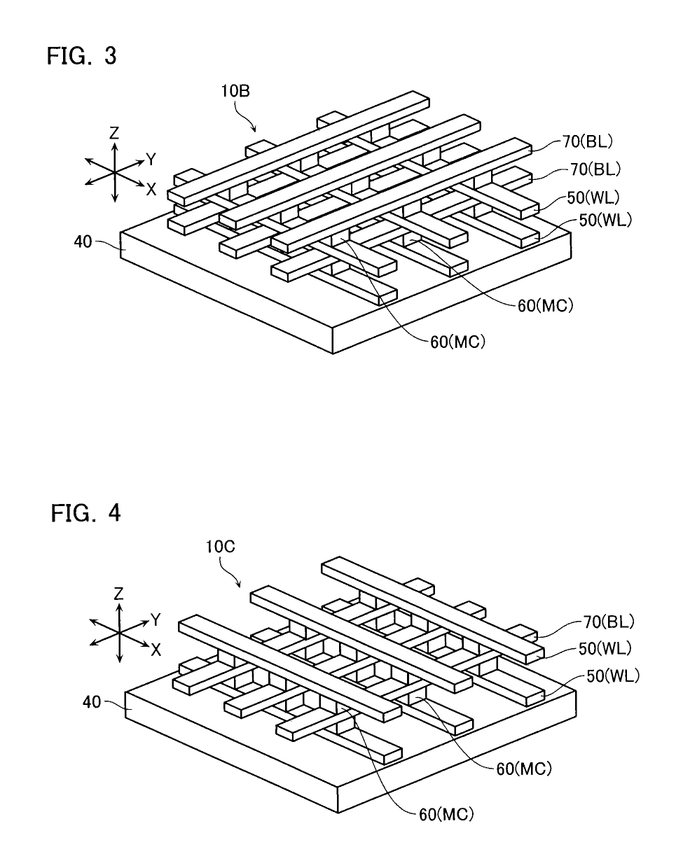

For example, the memory cell array 10 may be configured by a stacking structure 10B shown in FIG. 3. In addition to the configuration of the stacking structure 10A, the stacking structure 10B further includes the first conductive layer 50, the memory layer 60, and the second conductive layer 70 stacked in a layer above the stacking structure 10A (in the Z direction) via an insulating layer (not shown).

Moreover, the memory cell array 10 may be configured by a stacking structure 100 shown in FIG. 4. The stacking structure 100 includes the memory layer 60 formed in a layer above the second conductive layer 70 of the stacking structure 10A (in the Z direction), and the first conductive layer 50 formed in a layer above these memory layer 60 (in the Z direction). That is, in the stacking structure 100, the upper and lower memory layers 60 share the second conductive layer 70 that is between them.

In this first embodiment, description proceeds assuming the structure in FIG. 2.

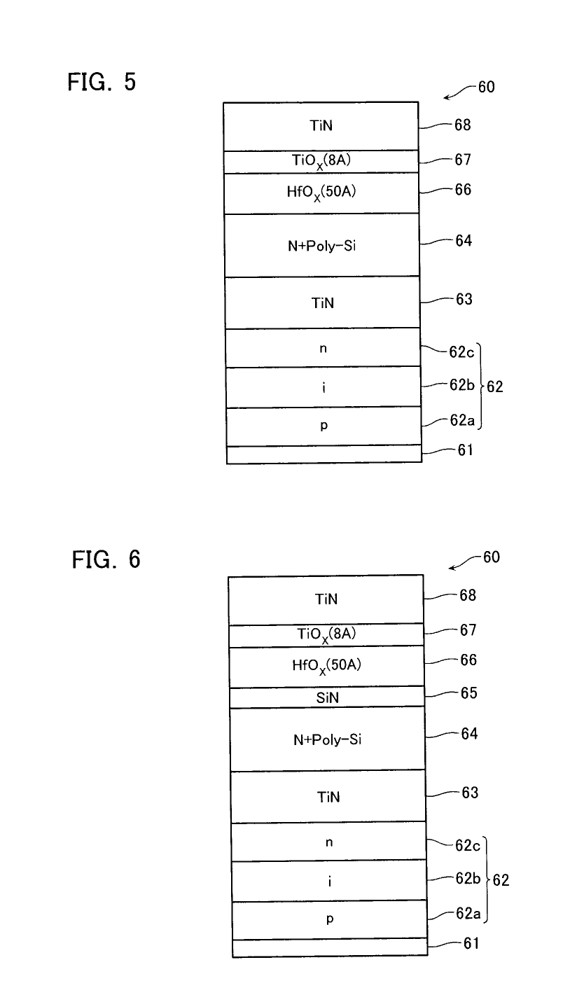

Next, a configuration of the memory layer 60 is described. FIG. 5 is a cross-sectional view showing a configuration of a memory layer in a comparative example. Note that FIG. 6 is a cross-sectional view showing the configuration of the memory layer 60 in the first embodiment.

The memory layer in the comparative example shown in FIG. 5 includes, from a lower layer to an upper layer, an electrode layer 61, a diode layer 62, an electrode layer 63, a polysilicon layer 64, a variable resistance layer 66, a variable resistance layer 67, and an electrode layer 68. The variable resistance element VR is formed by the two layers of the variable resistance layers 66 and 67.

The electrode layer 61 is formed by, for example, titanium nitride (TiN).

The diode layer 62 is formed in a layer above the electrode layer 61. The diode layer 62 functions as the previously-mentioned diode DI. The diode layer 62 may be configured having, for example, a MIM (Metal-Insulator-Metal) structure, a PIN (P+polysilicon-Intrinsic-N+polysilicon) structure, and so on.

The electrode layer 63 is formed in a layer above the diode layer 62. The electrode layer 63 may be formed by titanium nitride, similarly to the electrode layer 61. The electrode layers 61 and 63 may be formed from at least one kind or more of metals selected from “element group g1” shown below, or any of nitrides and carbides of the “element group g1” such as “compound group g1” shown below. Alternatively, the electrode layers 61 and 63 may be formed from a mixture of these “element group g1” and “compound group g1”.

Element group g1: tungsten (W), tantalum (Ta), silicon (Si), iridium (Ir), rubidium (Rb), gold (Au), platinum (Pt), palladium (Pd), molybdenum (Mo), nickel (Ni), chromium (Cr), cobalt (Co), and titanium (Ti).

Compound group g1: Ti—N, Ti—Si—N, Ta—N, Ta—Si—N, Ti—C, Ta—C, and W—N.

The polysilicon layer 64 is formed in a layer above the electrode layer 63. The variable resistance layer 66 is formed in a layer above this polysilicon layer 64, and the variable resistance layer 67 is further formed in a layer above this variable resistance layer 66. The variable resistance layer 66 is formed by a transition metal oxide. The transition metal is, for example, hafnium (Hf), manganese (Mn), zirconium (Zr), or the like. Now, although the description and drawings are for the case where hafnium is selected as an example, it is clear from the explanation below that similar advantages can be expected also in the case where other transition metals are employed. The variable resistance layer 66 may be formed by hafnium oxide (HfOx) with a film thickness of about 50 A. The variable resistance layer 67 need not be present, but when the variable resistance layer 67 is formed, it may be formed by titanium oxide (TiOx) with a film thickness of about 8 A. The variable resistance layers 66 and 67 function integrally as the variable resistance element VR in FIG. 1. The electrode layer 68 is formed in a layer above the variable resistance layer 67. The electrode layer 68 may be formed by an identical material to the electrode layers 61 and 63.

Next, a structure of the memory layer 60 in the first embodiment is described with reference to FIG. 6. The memory layer 60 in this first embodiment differs from the comparative example of FIG. 5 in comprising a block layer 65 between the polysilicon layer 64 and the variable resistance layer 66. In other respects, the memory layer in the present embodiment is identical in configuration to the comparative example. In FIG. 6, like elements as those of FIG. 6 will be assigned with the same reference numerals.

This block layer 65 is provided to prevent silicon (Si) in the polysilicon layer 64 from combining with hafnium (Hf) in the variable resistance layer 66 to form hafnium silicide (HfSi). As an example, the block layer 65 may be formed adopting a material such as silicon nitride (SiN), silicon oxynitride (SiON), or silicon oxide (SiO₂), and having a film thickness of about 1 nm.

In the comparative example of FIG. 5, because there is no block layer 65, silicon (Si) in the polysilicon layer 64 combines with hafnium (Hf) in the variable resistance layer 66, whereby a layer of hafnium silicide (HfSi) is formed in a vicinity of a boundary between the polysilicon layer 64 and the variable resistance layer 66.

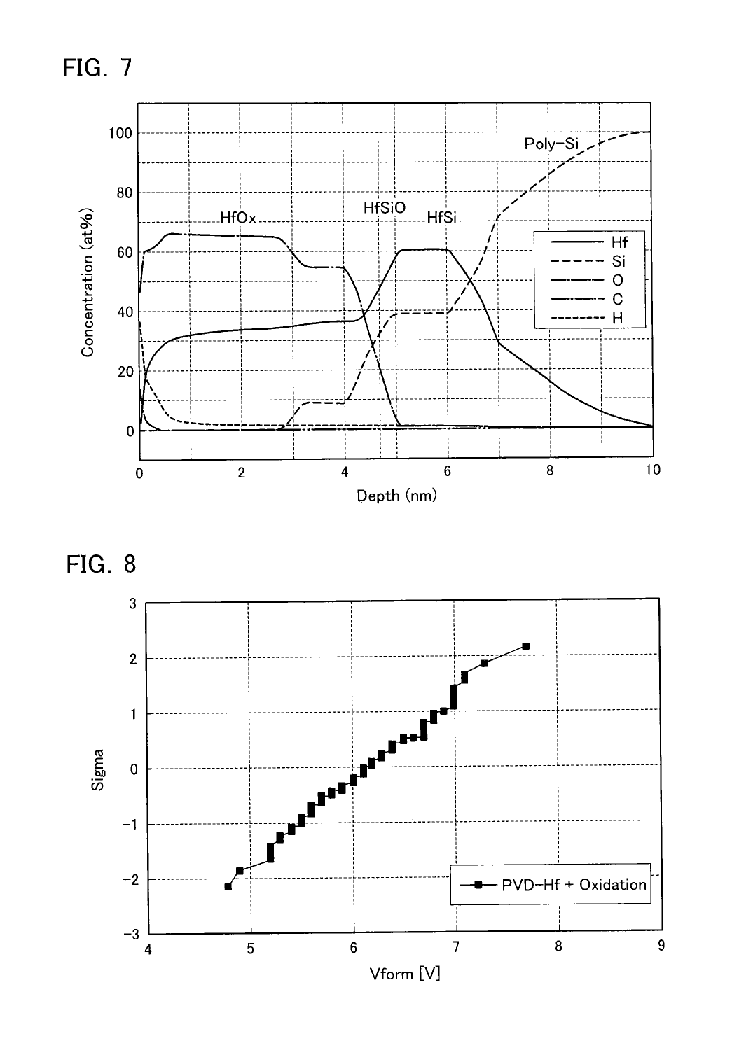

FIG. 7 shows a change in composition (in a depth direction) in this comparative example of FIG. 5. When depositing a HfOx film in the variable resistance layer 66, it is preferable that a process is performed in which a film of hafnium (Hf) is first formed by sputtering, and then the hafnium is oxidized by radical oxidation. As shown in FIG. 7, this film formation method allows a concentration gradient of oxygen to be formed in the depth direction. Providing such a concentration gradient allows an operating margin for resistance change occurring in the variable resistance layer 66 to be expanded.

However, when performing film formation of the HfOx film in the variable resistance layer 66 by sputtering and radical oxidation, the following problem arises. That is, as shown in FIG. 7, although in the variable resistance layer 66 separated from the vicinity of the boundary between the polysilicon layer 64 and the variable resistance layer 66, hafnium oxide (HfOx) Ox) is formed, in a region close to the boundary, HfSiO is formed, and in a region even closer to the boundary, hafnium silicide (HfSi) is formed. If a large amount of hafnium silicide is formed, there is a risk that characteristics of the variable resistance layer 66 change, whereby desired switching characteristics can no longer be obtained.

Moreover, when hafnium silicide (HfSi) is formed in the boundary between the polysilicon layer 64 and the variable resistance layer 66, a forming voltage required in a forming operation greatly varies among plurality of memory cells. FIG. 8 is a graph showing a relationship between a forming voltage V form when the variable resistance layer 66 is formed by sputtering of Hf and radical oxidation, and a ratio of memory cells for which the forming operation has been completed. As is clear from FIG. 8, when the variable resistance layer 66 is formed by sputtering of Hf and radical oxidation, forming by a low forming voltage is enabled. However, at the same time, effects of hafnium silicide lead also to the problem that the number of memory cells for which forming does not reach completion even at a high forming voltage increases, and variation among memory cells increases. Variation in forming voltage is a problem when carrying out the forming operation of a memory cell array.

Accordingly, in the present embodiment, as shown in FIG. 6, the block layer 65 is formed between the polysilicon layer 64 and the variable resistance layer 66 to suppress formation of hafnium silicide. This makes forming possible at a low forming voltage and allows variation in characteristics among the memory cells to be reduced.

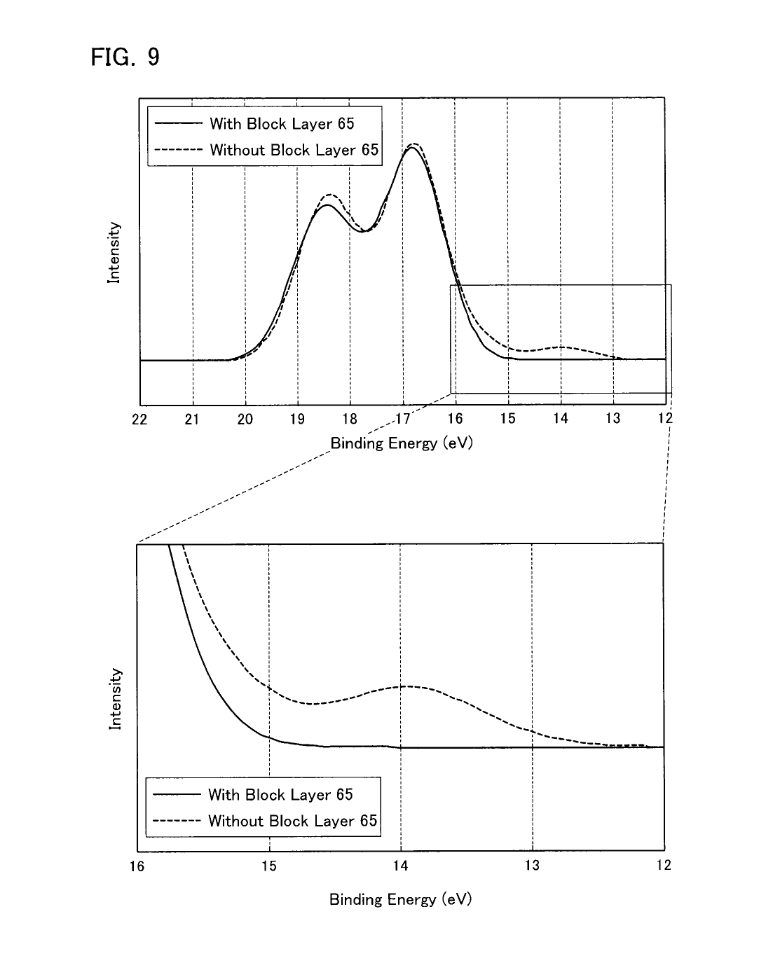

FIG. 9 shows the results of measuring spectroscopic characteristics of the memory layers of FIGS. 5 and 6 using an X-ray photoelectron spectroscopy (XPS) device. As shown in the enlarged view of the right side of FIG. 9, while in the memory layer of FIG. 5, a peak is observed in a vicinity of 14 eV corresponding to binding energy of hafnium silicide, in the memory layer of FIG. 6, the peak is not observed. This shows that hafnium silicide is not formed.

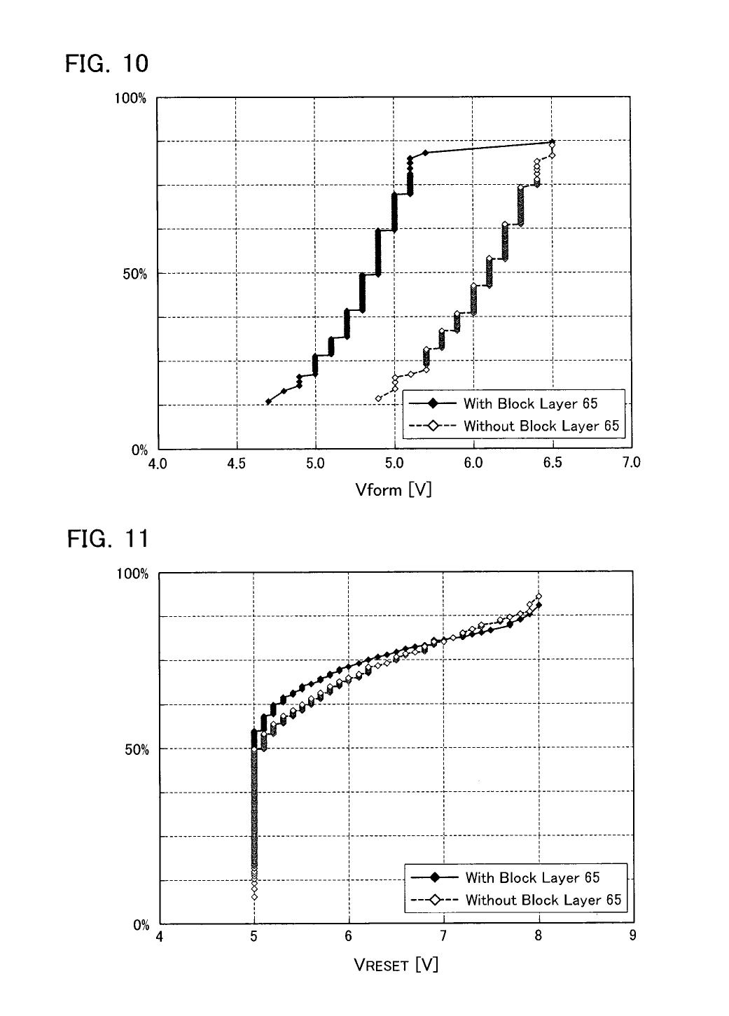

FIG. 10 is a graph showing a difference in characteristics of the forming operation between the memory layer without the block layer 65 as in FIG. 5 and the memory layer with the block layer 65 as in FIG. 6. As is clear from FIG. 10, the forming operation can be completed by a lower forming voltage when the block layer 65 is present (FIG. 6), compared to when the block layer 65 is absent (FIG. 5).

FIG. 11 is a graph showing a difference in characteristics of a resetting operation (operation to switch a memory cell from a low-resistance state to a high-resistance state) between the memory layer without the block layer 65 as in FIG. 5 and the memory layer with the block layer 65 as in FIG. 6. As is clear from FIG. 11, the resetting operation can be completed by a lower resetting voltage when the block layer 65 is present (FIG. 6), compared to when the block layer 65 is absent (FIG. 5).

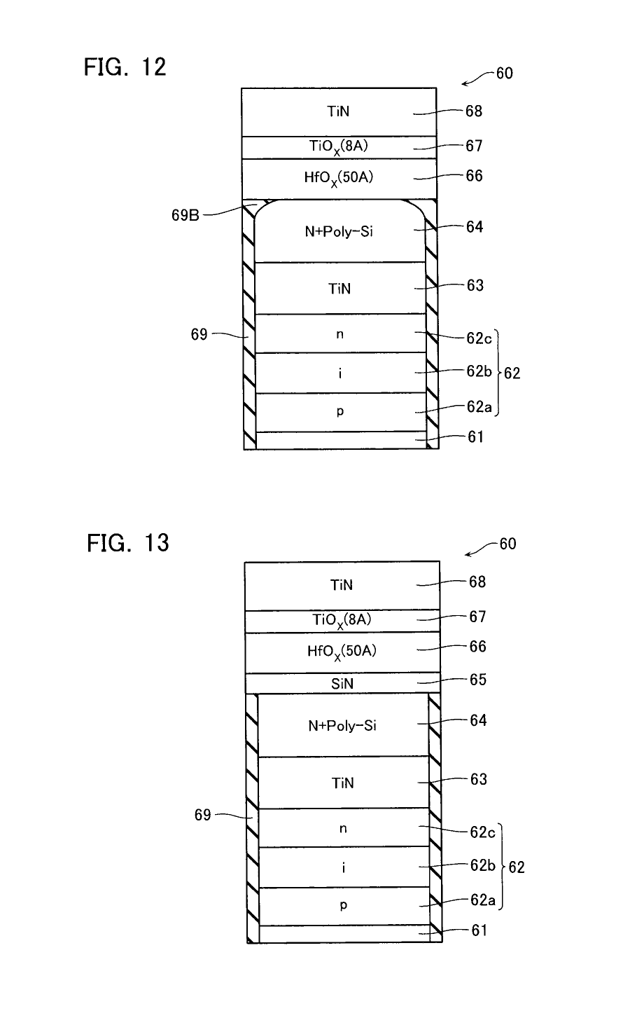

Another advantage of the block layer 65 will be described with reference to FIGS. 12 and 13. Due to the block layer 65 being formed, so-called bird's beak can be prevented from being formed in the polysilicon layer 64, whereby variation in characteristics of the memory layer 60 can be suppressed. That is, when the memory layer 60 is etched in a matrix, an interlayer insulating film is filled into the trench after etching. Due to effects of this interlayer insulating film, an oxide film 69 is formed in a side wall of the diode layer 62, the electrode layer 63, and the polysilicon layer 64. In this case, if there is no block layer 65, the polysilicon layer 64 is formed with an oxide film 69B (bird's beak) not only on its side surface but also its upper surface (boundary with the variable resistance layer 66). Formation of such bird's beak increases variation in characteristics of the variable resistance element VR and is thus undesirable.

In contrast, in the case of the memory layer comprising the block layer 65 as in FIG. 6, such bird's beak is not formed. Therefore, variation in characteristics of the variable resistance element VR can be suppressed.

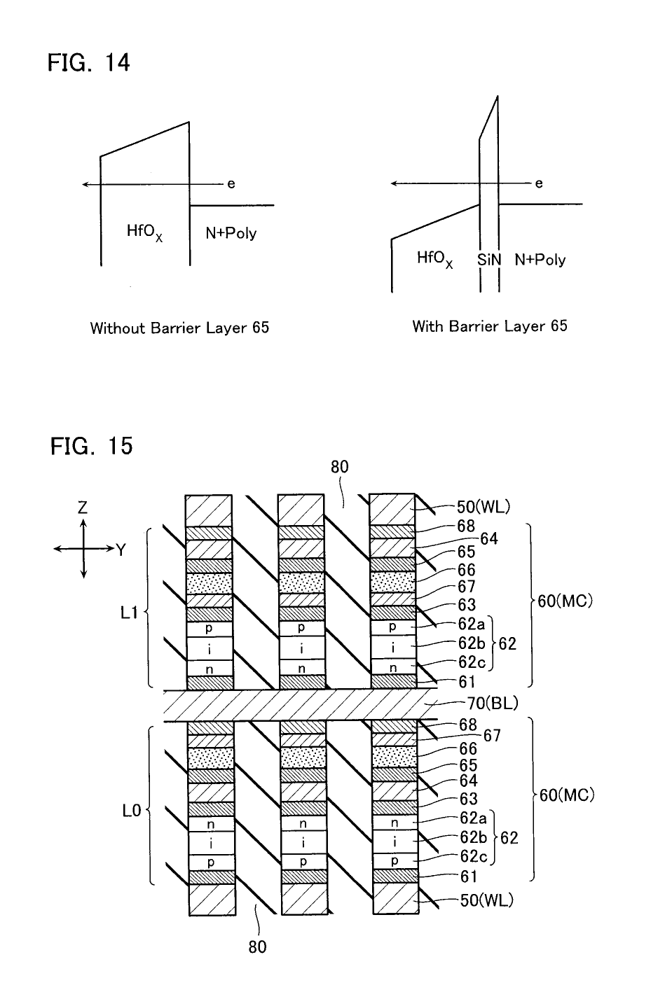

Next, yet another separate advantage of this block layer 65 will be described with reference to FIG. 14. Providing the block layer 65 results in a potential barrier of hafnium oxide in the variable resistance layer being lowered, whereby operating voltage can be reduced. That is, as shown in FIG. 14, when the block layer 65 formed by a silicon nitride film or the like is absent, the potential barrier of hafnium oxide is large, thus making it difficult for tunnel current to f low. This results in the problem that the forming operation, setting operation, and resetting operation all require application of a high voltage, whereby power consumption remains high.

On the other hand, when the block layer 65 formed a silicon nitride film or the like is present, only a potential barrier of the silicon nitride film of the block layer 65 remains between the variable resistance layer 66 and the polysilicon layer 64. The block layer 65 has an extremely thin film thickness of about 1 nm, hence allows tunnel current to flow easily. This enables applied voltages in the forming operation, setting operation, and resetting operation to be lowered, whereby power consumption can be reduced.

As described above, the present embodiment, by forming the block layer 65 between the polysilicon layer 64 and the variable resistance layer 66, allows variation in characteristics among memory cells to be suppressed, and also allows operating voltage to be lowered, whereby power consumption can be reduced.

### Second Embodiment

Next, a semiconductor memory device according to a second embodiment is described with reference to FIG. 15. As shown in FIG. 4, the semiconductor memory device of this embodiment has a structure in which word lines WL and bit lines BL are alternately stacked, and a memory cell array is formed between these word lines WL and bit lines BL. That is, two memory cell arrays adjacent in the stacking direction share bit lines BL or word lines WL.

FIG. 15 shows two memory cell arrays L0 and L1 from among a plurality of memory cell arrays stacked over multiple layers, and the bit lines BL and word lines WL connected to those two memory cell arrays L0 and L1. The memory cell arrays L0 and L1 share the bit lines BL.

The memory cell arrays L0 and L1 each include the diode layers 61. The diode layers 61 included in the memory cell arrays L0 and L1 are all formed having a direction from the word lines WL toward the bit lines BL as a forward direction. In other words, in the lower layer memory cell array L0, the diode layers 61 each comprise, sequentially from a lower layer side (word line side), a p type semiconductor layer 61a, an i type semiconductor layer 61b, and an n type semiconductor layer 61c. Conversely, in the upper layer memory cell array L1, the diode layers 61 each comprise, sequentially from an upper layer side (word line side), a p type semiconductor layer 61a, an i type semiconductor layer 61b, and an n type semiconductor layer 61c.

In addition, in the lower layer memory cell array L0, the polysilicon layer 64, the block layer 65, the variable resistance layer 66, and the variable resistance layer 67 are formed sequentially from below in a layer above the diode layer 61. Conversely, in the upper layer memory cell array L1, the polysilicon layer 64, the block layer 65, the variable resistance layer 66, and the variable resistance layer 67 are formed sequentially from above in a layer above the diode layer 61. In order to match characteristics of the memory cell arrays in each layer, an order of stacking is sometimes changed on a memory cell array basis.

In the lower layer memory cell array L0, it is possible to form the block layer 65 of silicon nitride on the polysilicon layer 64 by using an ALD method and radical nitridation.

On the other hand, in the upper layer memory cell array L1, the block layer 65 of SiN is formed in a layer above the variable resistance layer 66 configured from hafnium oxide (HfOx). In this case, instead of employing the above-described ALD method and radical nitridation, it is desirable to first form a thin SiO₂ film by the ALD method and then form silicon nitride or silicon oxynitride on that thin SiO₂ film by plasma nitridation. Note that the memory cell array L0 may be located above the shared bit line BL, and the memory cell array L1 may be located below the shared bit line BL.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a memory cell array configured as an arrangement of memory cells disposed at intersections of a plurality of first lines and a plurality of second lines formed so as to intersect one another, each of the memory cells comprising a variable resistance element; and
a control circuit configured to selectively drive the first lines and the second lines,
the variable resistance element being configured by a transition metal oxide film,
an electrode connected to the variable resistance element including a polysilicon electrode configured from polysilicon, and
a block layer being formed between the polysilicon electrode and the variable resistance element.

2. The semiconductor memory device according to claim 1, wherein
the block layer has a film thickness of about 1 nm.

3. The semiconductor memory device according to claim 1, wherein
the transition metal oxide film is an oxide film of hafnium (Hf).

4. The semiconductor memory device according to claim 3, wherein
the block layer has a film thickness of about 1 nm.

5. The semiconductor memory device according to claim 3, wherein
the block layer is configured by silicon nitride, silicon oxynitride, or silicon oxide.

6. The semiconductor memory device according to claim 3, wherein
the block layer is configured by silicon nitride.

7. The semiconductor memory device according to claim 5, wherein
the block layer has a film thickness of about 1 nm.

8. The semiconductor memory device according to claim 1, wherein
the block layer is a film configured by a material having a function to prevent silicon in the polysilicon electrode from combining with transition metal in the transition metal oxide film.

9. The semiconductor memory device according to claim 8, wherein
the block layer has a film thickness of about 1 nm.

10. The semiconductor memory device according to claim 8, wherein
the transition metal oxide film is an oxide film of hafnium (Hf).

11. The semiconductor memory device according to claim 1, wherein
the first lines and the second lines are arranged alternately along a direction perpendicular to a semiconductor substrate,
in a first memory cell array formed in a layer either above or below one of the first lines, a first block layer is formed in a layer above the polysilicon layer, and the transition metal oxide film is further formed on the block layer, and
in a second memory cell array formed in a layer on the opposite side of the first memory cell array with respect to the one of the first lines, a second block layer is formed in a layer above the transition metal oxide film, and the polysilicon layer is further formed on the block layer.

12. The semiconductor memory device according to claim 11, wherein
the block layer is configured by silicon nitride, silicon oxynitride, or silicon oxide.

13. The semiconductor memory device according to claim 11, wherein
the block layer is configured by silicon nitride.

14. The semiconductor memory device according to claim 11, wherein
the transition metal oxide film is an oxide film of hafnium (Hf).

15. The semiconductor memory device according to claim 11, wherein
the block layer has a film thickness of about 1 nm.

16. The semiconductor memory device according to claim 1, wherein
the block layer is configured by silicon nitride, silicon oxynitride, or silicon oxide.

17. The semiconductor memory device according to claim 1, wherein
the block layer is configured by silicon nitride.
